(19) United States
(12) Patent Application Publication
(10) Pub. No.: US 2026/0036636 A1
(43) Pub. Date: Feb. 5, 2026

(54) BATTERY SYSTEM

(71) Applicant: Prime Planet Energy & Solutions, Inc., Tokyo (JP)

(72) Inventor: Hideyuki SASAO, Ono-shi (JP)

(21) Appl. No.: 19/264,863

(22) Filed: Jul. 10, 2025

(30) Foreign Application Priority Data
Aug. 5, 2024 (JP) 2024-129088

(51) Int. Cl. G01R 31/3835

(52) U.S. Cl. CPC G01R 31/3835

(57) ABSTRACT

A battery system includes a battery unit including a plurality of battery cells, a controller electrically connected to the battery unit, a power supply source supplying electric power to the controller, and a voltage detection means disposed between the controller and the power supply source and detecting a voltage value of the power supply source. The voltage detection means includes a first resistor connected in series to the power supply source, a second resistor connected in series to the first resistor, an A/D converter electrically connected between the first resistor and the second resistor so as to branch to the second resistor, and a diode electrically connected between the first resistor and the A/D converter so as to be inversely connected to the power supply source and to branch to the second resistor.

### CROSS REFERENCE TO RELATED APPLICATIONS

The present application claims priority from Japanese Patent Application No. 2024-129088 filed on Aug. 5, 2024, which is incorporated by reference herein in its entirety.

### BACKGROUND

The present invention relates to battery systems.

JP 2006-353020 A, for example, discloses a power supply device for vehicles. The power supply device detects the voltage of a plurality of batteries with a voltage detection circuit and controls charging and discharging of the plurality of batteries.

The voltage detection circuit divides the voltage of the plurality of batteries with a resistive voltage divider circuit. The divided voltages of the plurality of batteries are sequentially switched by multiplexers and output to an A/D converter. The A/D converter converts the signals into digital signals and an arithmetic circuit detects the voltages of the batteries.

### SUMMARY

There exists a voltage detection means 150 that detects the voltage of a power supply source 140 supplying electric power to a controller (not shown) for arithmetic circuits or the like, as illustrated in FIG. 4. In this voltage detection means 150, for example, the power supply source 140, a diode 180, and first to third resistors 161 to 163 are connected in series to each other. An A/D converter 170 is connected, for example, between the second resistor 162 and the third resistor 163 so as to branch to the third resistor 163.

In such a voltage detection means 150, if the power supply source 140 is inversely connected, a voltage drop occurs due to the forward voltage that occurs in the diode 180 (the voltage toward the power supply source 140). As a consequence, there is a risk of degradation in the accuracy of detecting the voltage value of the power supply source 140.

In accordance with the present disclosure, a battery system includes a battery unit including a plurality of battery cells, a controller, a power supply source, and a voltage detection means. The controller is electrically connected to the battery unit. The power supply source supplies electric power to the controller. The voltage detection means is disposed between the controller and the power supply source and detects a voltage value of the power supply source. The voltage detection means includes a first resistor, a second resistor, an A/D converter, and a diode. The first resistor is connected in series to the power supply source. The second resistor is connected in series to the first resistor. The A/D converter is electrically connected between the first resistor and the second resistor so as to branch to the second resistor. The diode is electrically connected between the first resistor and the A/D converter, so as to be inversely connected to the power supply source and to branch to the second resistor.

In the battery system disclosed herein, the diode is connected so as to branch to the second resistor and inversely connected to the power supply source. Therefore, when the power supply source is connected properly, the voltage value of the power supply source can be detected accurately without being adversely affected by the voltage drop due to the diode. Even if the power supply source is inversely connected, electric current flows into the diode that is inversely connected. This allows the A/D converter to be unlikely to fail.

### BRIEF DESCRIPTION OF THE DRAWINGS

FIG. 1 is a schematic view illustrating a battery system according to an embodiment.

FIG. 2 is a schematic view illustrating a voltage detection means of the battery system according to the embodiment.

FIG. 3 is a schematic view illustrating a voltage detection means of a battery system according to a modified example.

FIG. 4 is a schematic view illustrating a voltage detection means in conventional art.

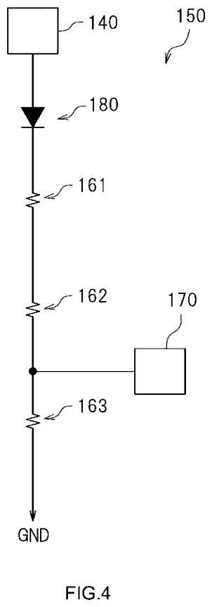

### DETAILED DESCRIPTION

Hereinbelow, embodiments of the technology according to the present disclosure will be described with reference to the drawings. It should be noted, however, that the embodiments disclosed herein are, of course, not intended to limit the invention. The drawings are schematic illustrations, and do not necessarily reflect any actual product. The features and components that exhibit the same effects are designated by the same reference symbols as appropriate, and the description thereof will not be repeated as appropriate.

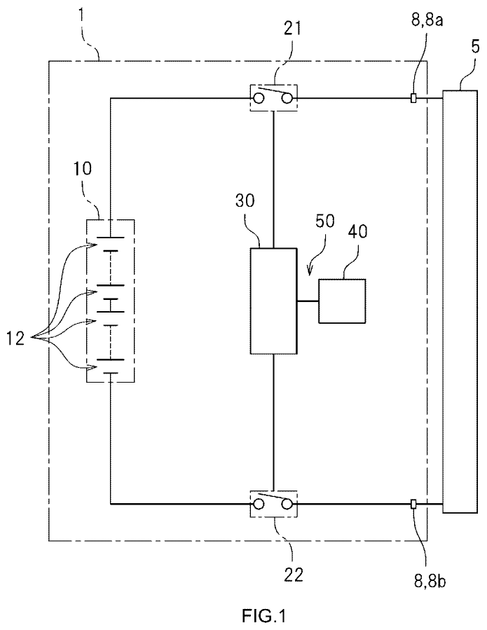

FIG. 1 is a schematic view illustrating a battery system 1 according to the present embodiment. As illustrated in FIG. 1, the battery system 1 is connected to a load 5. In the battery system 1, electric power is supplied from the battery unit 10 to the load 5. The load 5 is not particularly limited to any type of load. The load 5 may be, for example, a drive device, such as an electric motor, or an inverter or the like, of a vehicle. The load 5 may be connected to a smoothing capacitor for reducing abrupt changes in electric current. Herein, the battery system 1 is incorporated in, for example, vehicles such as hybrid electric vehicles, plug-in hybrid electric vehicles, and battery electric vehicles. In this case, the battery system 1 is used as the power source to supply electric power to the electric motors for propelling the vehicles. The battery system 1 is, however, not limited to those for use in vehicles.

As illustrated in FIG. 1, the battery system 1 includes a pair of output terminals 8, a battery unit 10, a first contactor 21, a second contactor 22, a controller 30, a power supply source 40, and a voltage detection means 50. The pair of output terminals 8 are connected to the load 5. The pair of output terminals 8 includes a positive electrode output terminal 8a and a negative electrode output terminal 8b.

The battery unit 10 is electrically connected to the pair of output terminals 8 and is connected indirectly to the load 5 via the pair of output terminals 8. The battery unit 10 is that which supplies electric power to the load 5. The load 5 may convert the electric power supplied from the battery unit 10 into motive power or supply regenerative power to the battery unit 10.

As illustrated in FIG. 1, the battery unit 10 includes a plurality of battery cells 12. The battery cells 12 are ones that are capable of being charged and discharged. For the battery cells 12, it may be possible to use secondary batteries, for example. Secondary batteries are batteries capable of repeated charging and discharging by the migration of charge carriers between a pair of electrodes (for example, positive electrode and negative electrode) through an electrolyte, for example. For the battery cells 12, it may be possible to use lithium-ion secondary batteries, nickel-metal hydride batteries, or the like, for example. In the present embodiment, the battery cells 12 are lithium-ion secondary batteries. The plurality of battery cells 12 are connected in series. Herein, the plurality of battery cells 12 are connected in series via a bus bar, not shown. However, it is also possible that the plurality of battery cells 12 may be connected in parallel. The number of battery cells 12 contained in the battery unit 10 is not limited to any particular number but may be a predetermined number. The number of battery cells 12 contained in the battery unit 10 may be determined as appropriate according to the magnitude of the electric power to be supplied to the load 5.

As illustrated in FIG. 1, the first contactor 21 is connected in series to the battery unit 10 (in other words, the plurality of battery cells 12 connected in series). Herein, the first contactor 21 is electrically connected to a positive electrode end of the battery unit 10. The first contactor 21 is disposed between the battery unit 10 and the positive electrode output terminal 8a. The first contactor 21 switches ON and OFF the electrical connection between the positive electrode end of the battery unit 10 and the load 5. Herein, contactors are, in other words, relays or switches.

As with the first contactor 21, the second contactor 22 is connected in series to the battery unit 10 (in other words, the plurality of battery cells 12 connected in series). Herein, the second contactor 22 is electrically connected to a negative electrode end of the battery unit 10. The second contactor 22 is disposed between the battery unit 10 and the negative electrode output terminal 8b. The second contactor 22 switches ON and OFF the electrical connection between the negative electrode end of the battery unit 10 and the load 5. In the present embodiment, the phrase “turning on a contactor” means that the contactor is in a connected state (i.e., in a closed state). The phrase “turning off a contactor” means that the contactor is in a disconnected state (i.e., in an open state). In the present embodiment, the first contactor 21 and the second contactor 22 are those that are capable of being switched ON and OFF electrically.

The controller 30 controls charging and discharging of the battery unit 10. In addition, the controller 30 detects the voltage value of the power supply source 40 (see FIG. 1), which is electrically connected to the controller 30. The configuration of the controller 30 is not limited to any particular configuration. The controller 30 may be, for example, a microcomputer. The controller 30 includes, for example, an I/F, a CPU, a ROM, and a RAM. The controller 30 may be composed of either a single computer or a plurality of computers. In the present embodiment, as illustrated in FIG. 1, the controller 30 is communicably connected to the first contactor 21 and the second contactor 22. The controller 30 controls switching of the first contactor 21 and the second contactor 22 between ON and OFF. Although not shown in the drawings, the controller 30 is electrically connected to the battery unit 10.

The power supply source 40 supplies electric power to the controller 30. In other words, the power supply source 40 supplies electric power to the controller 30 in order to operate the controller 30. In the present embodiment, the power supply source 40 is electrically connected to the controller 30. The power supply source 40 is not limited to any particular type. In the present embodiment, the power supply source 40 is a DC (direct current) power supply. For example, the power supply source 40 may be a lead-acid battery. However, the power supply source 40 may be an AC (alternating current) power supply. The power supply source 40 has a maximum voltage less than, for example, the battery unit 10. The power supply source 40 is a 12 V power supply. In the present embodiment, the user using the battery system 1, for example, may manually connect the power supply source 40 to the controller 30 or disconnect the power supply source 40 from the controller 30.

Next, the voltage detection means 50 according to the present embodiment will be described. The voltage detection means 50 detects the voltage value of the power supply source 40. The voltage detection means 50 is disposed between the controller 30 and the power supply source 40.

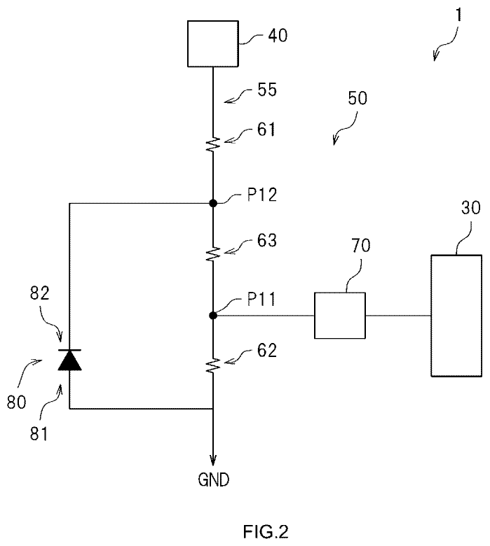

FIG. 2 is a schematic view illustrating the voltage detection means 50 of the battery system 1 according to the present embodiment. In the present embodiment, the battery system 1 includes a connecting wire 55, as illustrated in FIG. 2. The connecting wire 55 is a wire through which electric current flows. The connecting wire 55 is provided in the voltage detection means 50. One end of the connecting wire 55 is connected to the power supply source 40. The other end of the connecting wire 55 is connected to the ground.

In the present embodiment, as illustrated in FIG. 2, the voltage detection means 50 includes a first resistor 61, a second resistor 62, and a third resistor 63. The first resistor 61, the second resistor 62, and the third resistor 63 divide the voltage of the power supply source 40. The first resistor 61 is electrically connected to the power supply source 40. Herein, the first resistor 61 is connected in series to the power supply source 40. The first resistor 61 is disposed at an intermediate portion of the connecting wire 55, which is connected to the power supply source 40.

The second resistor 62 is electrically connected to the first resistor 61. Herein, the second resistor 62 is connected in series to the first resistor 61. The second resistor 62 is connected in series to the power supply source 40 via the first resistor 61. In the present embodiment, the second resistor 62 is disposed at an intermediate portion of the connecting wire 55. More specifically, the second resistor 62 is disposed at a portion of the connecting wire 55 that is closer to the ground than the first resistor 61 (in other words, opposite to the power supply source 40).

The third resistor 63 is disposed between the first resistor 61 and the second resistor 62. In the present embodiment, the third resistor 63 is disposed closer to the ground than the first resistor 61 and closer to the power supply source 40 than the second resistor 62. Herein, the first resistor 61, the third resistor 63, and the second resistor 62 are arranged in that order in a direction from the power supply source 40 toward the ground. The third resistor 63 is electrically connected to the first resistor 61 and the second resistor 62. The third resistor 63 is connected in series to the first resistor 61 and the second resistor 62. The third resistor 63 is connected in series to the power supply source 40 via the first resistor 61. In the present embodiment, the third resistor 63 is disposed at an intermediate portion of the connecting wire 55. More specifically, the third resistor 63 is disposed at a portion of the connecting wire 55 that is closer to the ground than the first resistor 61 and closer to the power supply source 40 than the second resistor 62.

As illustrated in FIG. 2, the voltage detection means 50 includes an A/D converter 70 and a diode 80. The A/D converter 70 converts analog signals into digital signals. In the present embodiment, the A/D converter 70 acquires the voltage value of the power supply source 40 in an analog signal. Thereafter, the A/D converter 70 converts the analog signal into a digital signal and then outputs it to the controller 30. In the present embodiment, the A/D converter 70 is electrically connected between the first resistor 61 and the second resistor 62. More specifically, the A/D converter 70 is connected between the second resistor 62 and the third resistor 63, which is disposed closer to the second resistor 62 than the first resistor 61. The A/D converter 70 is connected so as to branch to the second resistor 62. The A/D converter 70 is connected to an intermediate portion of the connecting wire 55. Herein, the A/D converter 70 is connected to a connecting point P11, which is disposed at an intermediate portion of the connecting wire 55. The connecting point P11 is disposed closer to the power supply source 40 than the second resistor 62. The connecting point P11 is disposed closer to the ground than the third resistor 63. The A/D converter 70 is electrically connected to the controller 30.

The diode 80 is electrically connected between the first resistor 61 and the A/D converter 70. More specifically, the diode 80 is connected between the first resistor 61 and the third resistor 63. The diode 80 is connected so as to branch to the second resistor 62 and the third resistor 63. The diode 80 is connected to an intermediate portion of the connecting wire 55. Herein, the diode 80 is connected to a connecting point P12, which is disposed at an intermediate portion of the connecting wire 55. The connecting point P12 is disposed closer to the ground (in other words, closer to the second resistor 62) than the first resistor 61. The connecting point P12 is disposed closer to the power supply source 40 than the second resistor 62 and the third resistor 63. The connecting point P12 is disposed between the first resistor 61 and the third resistor 63. The connecting point P12 is disposed closer to the power supply source 40 than the connecting point P11, to which the A/D converter 70 is connected.

In the present embodiment, the diode 80 is inversely connected to the power supply source 40. Herein, the diode 80 includes an anode 81 and a cathode 82. In the diode 80, the cathode 82 is disposed closer to the power supply source 40 than the anode 81. Herein, the cathode 82 is connected to a portion (the connecting point P12 herein) of the connecting wire 55 that is disposed between the first resistor 61 and the third resistor 63. The anode 81 is connected to the ground. In the present embodiment, the phrase “the diode 80 is inversely connected to the power supply source 40” indicates a state in which the positions of the anode 81 and the cathode 82 are inverse, which is a state in which the cathode 82 is disposed closer to the power supply source 40 than the anode 81. Note that the diode 80 is not limited to any particular type. The diode 80 may be what is called a Zener diode. By thus employing a Zener diode for the diode 80, the voltage detection means 50 can be protected from overvoltage even if the power supply source 40 results in overvoltage.

Next, the relationship of magnitude between the resistance values of the first resistor 61, the second resistor 62, and the third resistor 63 will be described. In the present embodiment, the second resistor 62 has a resistance value less than the first resistor 61. The second resistor 62 has a resistance value less than the third resistor 63. The first resistor 61 has a resistance value less than or equal to the third resistor 63. For example, the total of the resistance values of the first resistor 61 and the third resistor 63 is higher than the resistance value of the second resistor 62. In the present embodiment, the voltage value of the power supply source 40 is represented by V_{DD}, the resistance of the first resistor 61 is represented by R1, and the rated current of the diode 80 is represented by I. Then, the following expression (1) is satisfied.

V_{DD}/R1≤I (1)

In the present embodiment, it is preferable that the resistance value R1 of the first resistor 61 not be too high within the range in which the above expression (1) is satisfied. It is preferable that the resistance value R1 of the first resistor 61 be the minimum value of R1 when the above expression (1) is satisfied. Setting the resistance value R1 of the first resistor 61 to be not too high can prevent degradation of the detection accuracy. The resistance value R1 of the first resistor 61 may be about several kiloohms to about several ten kiloohms. The resistance value R1 of the first resistor 61 may be, for example, 10 kiloohms.

In the present embodiment, when the controller 30 acquires a detection value from the A/D converter 70. Then, based on the detection value, the controller 30 calculates (in other words, detectes) the voltage value of the power supply source 40. Herein, when the detection value by the A/D converter 70 is V, the voltage value of the power supply source 40 is V_{DD}, the resistance value of the first resistor 61 is R1, the resistance value of the second resistor 62 is R2, and the resistance value of the third resistor 63 is R3, the detection value V may be obtained by the following equation (2).

V=V_{DD}×R2/(R1+R2+R3) (2).

In the present embodiment, when detecting a voltage value of the power supply source 40 through the A/D converter 70, the controller 30 acquires a detection value with the voltage detection means 50. In the voltage detection means 50, the voltage of the power supply source 40 is divided by the first resistor 61, the second resistor 62, and the third resistor 63 according to the above equation (2) to obtain the detection value. The detection value is converted from an analog signal to a digital signal by the A/D converter 70 and is output to the controller 30. Based on the detection value acquired from the A/D converter 70, the controller 30 calculates a voltage value of the power supply source 40 to thereby detect the voltage value.

Thus, in the present embodiment, as illustrated in FIG. 1, the battery system 1 includes the battery unit 10 including the plurality of battery cells 12, the controller 30, the power supply source 40, and the voltage detection means 50. The controller 30 is electrically connected to the battery unit 10. The power supply source 40 supplies electric power to the controller 30. As illustrated in FIG. 2, the voltage detection means 50 is disposed between the controller 30 and the power supply source 40 and detects a voltage value of the power supply source 40. The voltage detection means 50 includes the first resistor 61, the second resistor 62, the A/D converter 70, and the diode 80. The first resistor 61 is connected in series to the power supply source 40. The second resistor 62 is connected in series to the first resistor 61. The A/D converter 70 is electrically connected between the first resistor 61 and the second resistor 62 so as to branch to the second resistor 62. The diode 80 is electrically connected between the first resistor 61 and the A/D converter 70 in such a manner to be inversely connected to the power supply source 40 and to branch to the second resistor 62. Thus, in the present embodiment, the diode 80 is connected so as to branch to the second resistor 62 and also inversely connected to the power supply source 40. Herein, the diode 80 includes an anode 81 and a cathode 82. The diode 80 is connected so that the cathode 82 is disposed closer to the power supply source 40 than the anode 81. When the power supply source 40 is connected properly, the voltage value of the power supply source 40 can be detected accurately without being adversely affected by the voltage drop due to the diode 80. Even if the power supply source 40 is inversely connected, electric current flows into the diode 80 that is inversely connected. This allows the A/D converter 70 to be unlikely to fail. Herein, the phrase “the power supply source 40 is inversely connected” means that the power supply source 40 is electrically inversely connected, which means a state in which the positive electrode and the negative electrode of the power supply source 40 is oppositely connected.

In the present embodiment, as illustrated in FIG. 2, the voltage detection means 50 includes the third resistor 63, which is disposed between the first resistor 61 and the second resistor 62 and closer to the power supply source 40 than the A/D converter 70 and is connected in series with the first resistor 61. This allows the voltage of the power supply source 40 to be divided by the first resistor 61, the second resistor 62, and the third resistor 63.

In the present embodiment, the diode 80 is electrically connected between the first resistor 61 and the third resistor 63 so as to branch to the third resistor 63. In such a case as well, even if the power supply source 40 is inversely connected, electric current flows into the diode 80 that is inversely connected. This allows the A/D converter 70 to be unlikely to fail.

In the present embodiment, the first resistor 61 has a resistance value less than or equal to the third resistor 63. This reduces the voltage drop due to the leakage current flowing into the diode 80. Therefore, the voltage value of the power supply source 40 can be detected accurately without being adversely affected by the leakage current due to the diode 80.

In the present embodiment, the expression V_{DD}/R1≤1 (see the above expression (1)) is satisfied, where V_{DD} is the voltage value of the power supply source 40, R1 is the resistance of the first resistor 61, and I is the rated current of the diode 80. This allows the electric current flowing into the diode 80 to be lower than the rated current of the diode 80 even if the power supply source 40 is inversely connected.

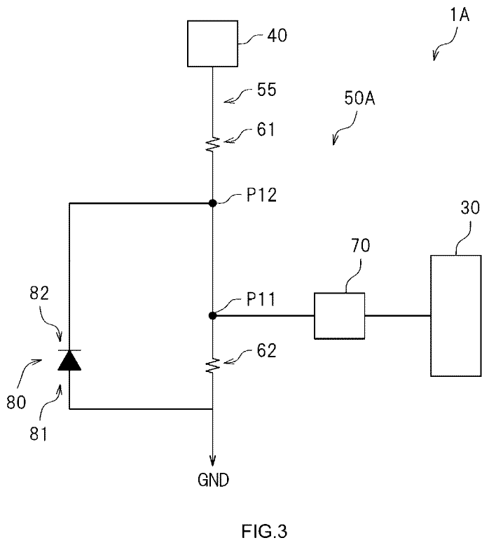

As illustrated in FIG. 2, the voltage detection means 50 of the battery system 1 includes the first resistor 61, the second resistor 62, and the third resistor 63, so the number of resistors is 3 in the present embodiment. However, as illustrated in the modified example shown in FIG. 3, a voltage detection means 50A of a battery system 1A includes a first resistor 61 and a second resistor 62, which means that the number of resistors may be 2. In other words, in FIG. 2, the third resistor 63 may be omitted. The modified example of FIG. 3 is able to obtain the same advantageous effects as those obtained by the present embodiment.

In the present embodiment, as illustrated in FIG. 2, the connecting point P12 to which the diode 80 is connected is disposed at a portion of the connecting wire 55 that is between the first resistor 61 and the third resistor 63. However, the connecting point P12 may be disposed at a portion of the connecting wire 55 that is between the third resistor 63 and the connecting point P11 to which the A/D converter 70 is connected. In other words, the diode 80 may be connected between the third resistor 63 and a portion of the connecting wire 55 to which the A/D converter 70 is connected.

As has been described above, the present description contains the disclosure as set forth in the following items.

### Item 1:

A battery system including:
a battery unit including a plurality of battery cells;
a controller electrically connected to the battery unit;
a power supply source supplying electric power to the controller; and
a voltage detection means disposed between the controller and the power supply source, and detecting a voltage value of the power supply source, wherein:
the voltage detection means includes:
   a first resistor connected in series to the power supply source;
   a second resistor connected in series to the first resistor;
   an A/D converter electrically connected between the first resistor and the second resistor so as to branch to the second resistor; and
   a diode electrically connected between the first resistor and the A/D converter, so as to be inversely connected to the power supply source and to branch to the second resistor.

### Item 2:

The battery system according to item 1, wherein the voltage detection means includes a third resistor disposed between the first resistor and the second resistor and closer to the power supply source than the A/D converter, and connected in series to the first resistor.

### Item 3:

The battery system according to item 2, wherein the diode is electrically connected between the first resistor and the third resistor, so as to branch to the third resistor.

### Item 4:

The battery system according to item 2 or 3, wherein the first resistor has a resistance less than or equal to the third resistor.

### Item 5:

The battery system according to any one of items 2 through 4, wherein V_{DD}/R1≤I is satisfied, where V_{DD} is a voltage value of the power supply source, R1 is a resistance value of the first resistor, and I is a rated current of the diode.

### Item 6:

The battery system according to any one of items 1 to 5, wherein:
the diode includes an anode and a cathode; and
the diode is connected so that the cathode is disposed closer to the power supply source than the anode.

What is claimed is:

1. A battery system comprising:
a battery unit including a plurality of battery cells;
a controller electrically connected to the battery unit;
a power supply source supplying electric power to the controller; and
a voltage detection means disposed between the controller and the power supply source, and detecting a voltage value of the power supply source, wherein:
the voltage detection means includes:
a first resistor connected in series to the power supply source;
a second resistor connected in series to the first resistor;
an A/D converter electrically connected between the first resistor and the second resistor so as to branch to the second resistor; and
a diode electrically connected between the first resistor and the A/D converter, so as to be inversely connected to the power supply source and to branch to the second resistor.

2. The battery system according to claim 1, wherein the voltage detection means includes a third resistor disposed between the first resistor and the second resistor and closer to the power supply source than the A/D converter, and connected in series to the first resistor.

3. The battery system according to claim 2, wherein the diode is electrically connected between the first resistor and the third resistor, so as to branch to the third resistor.

4. The battery system according to claim 2, wherein the first resistor has a resistance less than or equal to the third resistor.

5. The battery system according to claim 2, wherein V_{DD}/R1≤I is satisfied, where V_{DD} is a voltage value of the power supply source, R1 is a resistance value of the first resistor, and I is a rated current of the diode.

6. The battery system according to claim 1, wherein:
the diode includes an anode and a cathode; and
the diode is connected so that the cathode is disposed closer to the power supply source than the anode.
